(19) United States
(12) Patent Application Publication
(10) Pub. No.: US 2026/0122792 A1
(43) Pub. Date: Apr. 30, 2026

(54) CURABLE RESIN COMPOSITION, DRY FILM, CURED PRODUCT, AND PRINTED WIRING BOARD

(71) Applicant: TAIYO HOLDINGS CO., LTD., Saitama-ken (JP)

(72) Inventors: Yumi KONDO, Saitama-ken (JP); Yoshitomo AOYAMA, Saitama-ken (JP); Mami NOSAKA, Saitama-ken (JP); Takumi SUZUKI, Saitama-ken (JP); Kota OKI, Saitama-ken (JP); Kazutaka NAKADA, Saitama-ken (JP)

(21) Appl. No.: 19/370,451

(22) Filed: Oct. 27, 2025

(30) Foreign Application Priority Data
Oct. 31, 2024 (JP) 2024-192351

(51) Int. Cl. H05K 3/46; B32B 15/082; B32B 15/20; B32B 37/06; B32B 37/10; C08L 53/02; C08L 71/12; H05K 1/03

(52) U.S. Cl. CPC H05K 3/46; B32B 15/082; B32B 15/20; B32B 37/06; B32B 37/1018; C08L 53/02; C08L 71/126; H05K 1/036; B32B 2307/204; B32B 2457/08; C08L 2207/04; H05K 2201/012; H05K 2201/0158

(57) ABSTRACT

The present invention provides a curable resin composition comprising a polyphenylene ether resin, which can simultaneously achieve excellent storage stability, excellent adhesion between the cured product and a conductor layer at high temperatures, and excellent dielectric properties of the cured product. In a curable resin composition comprising a polyphenylene ether resin, a styrene-based elastomer resin, and a polymerization initiator, a styrene-based elastomer resin having a soft segment composed of styrene and one or more monomers other than styrene is used as the styrene-based elastomer resin, the melt flow rate of the styrene-based elastomer resin is adjusted to 15.0 g/10 min or less, and the styrene ratio of the styrene-based elastomer resin is adjusted to 65% by mass or more.

### BACKGROUND OF THE INVENTION

### Field of the Invention

The present invention relates to a curable resin composition, particularly to a curable resin composition suitable for forming an insulating layer. The present invention also relates to a dry film having a resin layer consisting of the curable resin composition, a cured product of the curable resin composition or the resin layer of the dry film, and a printed wiring board having the cured product.

### Background Technology

In recent years, with the increasing volume of information processing, there has been an increased need for finer and denser circuit wiring in circuit boards, which are widely used in various electronic devices, in order to reduce the size and improve the functionality of these devices. Furthermore, the spread of high-capacity, high-speed communications, such as fifth-generation (5G) communications systems, and millimeter-wave radar for automotive ADAS (Advanced Driver Assistance Systems), has led to increasingly higher frequencies in electronic device signals. Therefore, the insulating film for the redistribution layer of the latest high-density semiconductor packages is particularly required to meet the demands of high resolution to accommodate the miniaturization associated with higher integration, as well as excellent dielectric properties, such as low dielectric constant and low dielectric loss tangent, to suppress transmission loss in the high-frequency band.

Thermosetting resins or photosensitive resins are generally used as materials for forming insulating layers. Epoxy resins and ester resins are commonly used as thermosetting resins, but because their relative dielectric constants and dielectric dissipation factors are not sufficiently low, the higher the frequency band, the greater the transmission loss due to dielectric loss, resulting in problems such as signal attenuation and heat generation. Therefore, in recent years, the formation of insulating layers using polyphenylene ether, which has excellent low dielectric properties, has attracted attention.

However, polyphenylene ether has low compatibility with resins commonly used in forming insulating layers and low solubility in solvents, and therefore, there is a problem that resin compositions comprising polyphenylene ether sometimes have insufficient storage stability.

Furthermore, curable resin compositions used to form insulating layers for electronic components are required to form a cured product having sufficient adhesion to conductor layers at high temperatures, such as during reflow soldering processes.

In order to solve the problems of compatibility and solubility of polyphenylene ether, for example, Patent Document 1 proposes a technique of improving compatibility with other resin components and solubility in solvents by branching the polyphenylene ether chain. Furthermore, Patent Document 2 proposes a technique of improving compatibility by using two types of polyphenylene ether resins with different durometer hardnesses in combination in a composition. However, these patent documents make no mention of the storage stability of resin compositions comprising polyphenylene ether or the adhesion between the cured product and a conductor layer at high temperatures.

### PRIOR ART DOCUMENTS

### Patent Documents

[Patent Document 1] JP 2022-186708 A
[Patent Document 2] International Publication No. 2021/010432

### SUMMARY OF THE INVENTION

### Problem to be Solved by the Invention

Under these circumstances, it remains a continuing technical problem to simultaneously achieve excellent storage stability, excellent adhesion between the cured product and a conductor layer at high temperatures, and excellent dielectric properties of the cured product in a curable resin composition comprising a polyphenylene ether resin.

Therefore, an object of the present invention is to provide a curable resin composition comprising a polyphenylene ether resin, which has excellent storage stability, excellent adhesion between the cured product and a conductor layer at high temperatures, and excellent dielectric properties of the cured product. Another object of the present invention is to provide a dry film having a resin layer consisting of such a curable resin composition, a cured product of the curable resin composition or the resin layer of the dry film, and a printed wiring board having the cured product.

### Means for Solving the Problem

As a result of intensive investigation, the present inventors have found that the above-mentioned problems can be solved by a curable resin composition comprising a polyphenylene ether resin, a styrene-based elastomer resin, and a polymerization initiator, wherein a styrene-based elastomer resin having a soft segment composed of styrene and one or more monomers other than styrene is used as the styrene-based elastomer resin, the melt flow rate of the styrene-based elastomer resin is adjusted to 15.0 g/10 min or less, and the styrene ratio of the styrene-based elastomer resin is adjusted to 65% by mass or more, and have thus completed the present invention. That is, the summary of the present invention is as follows.

[1] A curable resin composition comprising a polyphenylene ether resin, a styrene-based elastomer resin, and a polymerization initiator, wherein
the styrene-based elastomer resin has a soft segment, and the soft segment is composed of styrene and one or more monomers other than styrene,
the melt flow rate of the styrene-based elastomer resin is 15.0 g/10 min or less, and
the styrene ratio of the styrene-based elastomer resin is 65% by mass or more.

[2] The curable resin composition according to [1], wherein the solubility parameter of the soft segment is 17.0 or more.

[3] The curable resin composition according to [1] or [2], wherein the soft segment of the styrene-based elastomer resin is fully hydrogenated.

[4] The curable resin composition according to any one of [1] to [3], which is substantially free of a dispersant.

[5] A dry film having a first film and a resin layer provided on at least one surface of the first film, wherein the resin layer consists of the curable resin composition according to any one of [1] to [4].

[6] A cured product of the curable resin composition according to any one of [1] to [4] or the resin layer of the dry film according to [5].

[7] A printed wiring board having the cured product according to [6].

### Effects of the Invention

According to the present invention, it is possible to provide a curable resin composition comprising a polyphenylene ether resin, which simultaneously achieves excellent storage stability, excellent adhesion between the cured product and a conductor layer at high temperatures, and excellent dielectric properties of the cured product. Furthermore, according to the present invention, it is possible to provide a dry film having a resin layer made of such a curable resin composition, a cured product of the curable resin composition or the resin layer of the dry film, and a printed wiring board having the cured product.

### DETAILED DESCRIPTION OF THE INVENTION

### [Curable Resin Composition]

According to one aspect of the present invention, there is provided a curable resin composition (hereinafter also referred to as “the curable resin composition of the present invention”). The curable resin composition of the present invention can be suitably used for forming an insulating layer in a printed wiring board or the like. In particular, the curable resin composition of the present invention is inhibited from increasing in fluidity at high temperatures, and the styrene-based elastomer resin and the polyphenylene ether resin are sufficiently compatible with each other, resulting in excellent storage stability.

The curable resin composition of the present invention comprises a polyphenylene ether resin, a styrene-based elastomer resin, and a polymerization initiator as essential components. Each component of the curable resin composition of the present invention will be described in detail below. Note that each component may be commercially available or may be appropriately synthesized.

### (Polyphenylene Ether Resin)

The curable resin composition of the present invention comprises a polyphenylene ether resin. Since the molecular structure of polyphenylene ether resin is highly symmetric, the dielectric constant of a cured product of the curable resin composition can be reduced when the curable resin composition comprises the polyphenylene ether resin. Furthermore, since the polyphenylene ether resin stacks at a high density due to the interaction between its ring structures, resulting in a high crosslink density, the water absorption rate of a cured product of the curable resin composition can be reduced, and thereby the dielectric constant can be reduced, when the curable resin composition comprises the polyphenylene ether resin.

The polyphenylene ether resin is not particularly limited as long as it has phenylene ether units as repeating structural units, and any conventionally known polyphenylene ether resin can be used. Specific examples of polyphenylene ether resins include polymers having structural units represented by the following structural formula in the main chain (preferably, polyphenylene ether polymers in which the structural units represented by the following structural formula account for 90 mol % or more of all structural units excluding terminal groups). The polyphenylene ether resin may be a homopolymer or a copolymer. Furthermore, the polyphenylene ether resin may be used alone or in combination of two or more types.

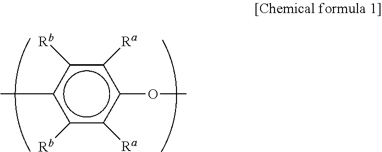

[In the formula,
two R^{a} each independently represent a hydrogen atom, a halogen atom, a primary or secondary alkyl group, an aryl group, an aminoalkyl group, a halogenated alkyl group, a hydrocarbonoxy group or a halogenated hydrocarbonoxy group;
two R^{b} each independently represent a hydrogen atom, a halogen atom, a primary or secondary alkyl group, an aryl group, a halogenated alkyl group, a hydrocarbonoxy group or a halogenated hydrocarbonoxy group;
provided that two R^{a} cannot both be hydrogen atoms.]

R^{a} and R^{b} are preferably each independently a hydrogen atom, a primary or secondary alkyl group or an aryl group. Examples of primary alkyl groups include methyl group, ethyl group, n-propyl group, n-butyl group, n-amyl group, isoamyl group, 2-methylbutyl group, 2,3-dimethylbutyl group, 2-, 3- or 4-methylpentyl group, heptyl group and the like. Examples of secondary alkyl groups include isopropyl group, sec-butyl group, 1-ethylpropyl group and the like. R^{a} is particularly preferably a primary or secondary alkyl group having 1 to 4 carbon atoms or a phenyl group. R^{b} is preferably a hydrogen atom. Because the polyphenylene ether resin does not have a highly polar substituent, the dielectric properties of the cured product of the curable resin composition of the present invention are excellent (i.e., the curable resin composition of the present invention has a lower dielectric tangent).

Examples of homopolymers of polyphenylene ether resins include polymers of 2,6-dialkylphenylene ether such as poly(2,6-dimethyl-1,4-phenylene) ether, poly(2,6-diethyl-1,4-phenylene ether), poly(2,6-dipropyl-1,4-phenylene ether), poly(2-ethyl-6-methyl-1,4-phenylene ether) and poly(2-methyl-6-propyl-1,4-phenylene ether). Furthermore, examples of copolymers of polyphenylene ether resins include 2,6-dialkylphenol/2,3,6-trialkylphenol copolymers such as 2,6-dimethylphenol/2,3,6-trimethylphenol copolymer, 2,6-dimethylphenol/2,3,6-triethylphenol copolymer, 2,6-diethylphenol/2,3,6-trimethylphenol copolymer and 2,6-dipropylphenol/2,3,6-trimethylphenol copolymer; graft copolymers obtained by graft polymerizing styrene onto poly(2,6-dimethyl-1,4-phenylene ether); and graft copolymers obtained by graft polymerizing styrene onto 2,6-dimethylphenol/2,3,6-trimethylphenol copolymer.

In the present invention, various molecular weights (number average molecular weight, weight average molecular weight) of resin components including polyphenylene ether resin can be measured by gel permeation chromatography (GPC) as polystyrene-equivalent molecular weights.

The polyphenylene ether resin may have a main chain structure that is either a linear structure or a branched structure. Polyphenylene ether resins having a branched structure (hereinafter also referred to as “branched polyphenylene ether resins”) will be described in detail below.

A branched polyphenylene ether resin is a polyphenylene ether resin synthesized from raw material phenols, including phenols having hydrogen atoms at the ortho and para positions. Because such phenols have hydrogen atoms at the ortho positions, ether bonds can be formed not only at the ipso and para positions but also at the ortho position when oxidatively polymerized with phenols. Therefore, polyphenylene ether resins synthesized using such phenols as raw material phenols can form a branched structure. Such branched polyphenylene ether resins have excellent solubility in solvents and excellent compatibility and reactivity with each component in the curable resin composition.

Examples of branched polyphenylene ether resins include the polyphenylene ether resins disclosed in WO 2020/017570 A1.

The branched polyphenylene ether resin may be obtained by either of the following methods: (Method 1) a method of synthesizing a polyphenylene ether resin using, as a raw material phenol, a phenol comprising a functional group having an unsaturated carbon bond; or (Method 2) a method of synthesizing a polyphenylene ether resin using, as a raw material phenol, a phenol not comprising a functional group having an unsaturated carbon bond, and then modifying the obtained polyphenylene ether resin to introduce a functional group having an unsaturated carbon bond into the polyphenylene ether resin.

The branched polyphenylene ether resin may be a mixture of two or more polyphenylene ether resins made from different types of raw material phenols.

The amount of functional groups having unsaturated carbon bonds in the branched polyphenylene ether resin is not particularly limited as long as the effects of the present invention are achieved, and is preferably within a range that does not significantly change the electrical properties of the polyphenylene ether structure and that allows for the formation of an effective crosslinked structure. Specifically, the amount of functional groups having unsaturated carbon bonds, as a molar ratio relative to all monomers constituting the branched polyphenylene ether resin, is preferably 3% or more, more preferably 6% or more, even more preferably 50% or less, and particularly preferably 25% or less. When the amount of functional groups having unsaturated carbon bonds in the polyphenylene ether resin is within the above-mentioned range, the amount of unreacted unsaturated carbon bonds can be reduced when the layer of the resin composition is cured, improving the crosslink density and the dielectric properties.

Furthermore, the higher the degree of branching of the branched polyphenylene ether resin, the more complex the entanglement of the molecular chains, resulting in a tougher coating film of the layer of the resin composition. Furthermore, when the degree of branching of the branched polyphenylene ether resin is high, the interaction between the ring structures in the polyphenylene ether resin in the curable resin composition before curing is alleviated, increasing the degree of freedom of the molecular chain of the polyphenylene ether resin. This increases the reactivity of the polyphenylene ether resin and improves the reaction rate. As a result, effects such as a lower dielectric constant of the resin composition and a tougher coating film are expected.

In the present invention, the branched structure (degree of branching) of the branched polyphenylene ether resin can be confirmed according to the following analytical procedure.

### (Analysis Procedure)

A chloroform solution of branched polyphenylene ether resin is prepared at concentrations of 0.1 mg/ml, 0.15 mg/ml, 0.2 mg/ml and 0.25 mg/mL, and a graph showing the correlation between refractive index difference and concentration is created while the solution is pumped at 0.5 mL/min, and the refractive index increment dn/dc is calculated from the slope. The absolute molecular weight is then measured under the following instrument operating conditions. Using the chromatograms from the RI detector and the MALS detector, a regression line is calculated by the least squares method from a logarithmic plot (conformation plot) of absolute molecular weight versus radius of gyration, and its slope is calculated.

### (Measurement Conditions)

Device name: HLC-8320GPC (manufactured by Tosoh Corporation)
Mobile phase: chloroform
Column: TSKgel (registered trademark) guardcolumn H_{HR}-H+TSKgel (registered trademark) GMH_{HR}-H (2 columns)+TSKgel (registered trademark) G2500H_{HR} (both manufactured by Tosoh Corporation)
Flow rate: 0.6 mL/min
Detector: Multi-angle static light scattering (MALS) detector DAWN (registered trademark) HELEOS+RI Detector Optilab (registered trademark) rEX (wavelength 254 nm) (both manufactured by WYATT TECHNOLOGY)
Sample concentration: 0.5 mg/ml
Sample solvent: Same as mobile phase. Dissolve 5 mg of sample in 10 mL of mobile phase.
Injection volume: 200 μL
Filter: 0.45 μm
STD reagent: Standard polystyrene molecular weight 37,900
STD concentration: 1.5 mg/ml
STD solvent: Same as the mobile phase. Dissolve 15 mg of sample in 10 ml of mobile phase.
Analysis time: 100 min

For resins with the same absolute molecular weight, the higher the degree of branching of the polymer chain, the smaller the distance from the center of gravity to each segment (radius of gyration). Therefore, the slope calculated from the logarithmic plot of the absolute molecular weight and radius of gyration obtained by GPC-MALS described above indicates the degree of branching of the branched polyphenylene ether resin, with a smaller slope indicating a higher degree of branching of the branched polyphenylene ether resin. In other words, the smaller the slope calculated from the above conformation plot, the more branches the branched polyphenylene ether resin has, and the greater the slope, the less branches the branched polyphenylene ether resin has.

For the branched polyphenylene ether resin, the above-mentioned slope is preferably less than 0.6, more preferably 0.50 or less, and even more preferably 0.40 or less. When the slope is within the above-mentioned range, the branched polyphenylene ether resin is considered to have sufficient branching. The lower limit of the slope is not particularly limited, but can be, for example, 0.05 or more or 0.20 or more.

Alternatively, a polyphenylene ether resin having a linear structure synthesized by the following procedure can also be used as the polyphenylene ether resin. First, 5.3 g of di-μ-hydroxo-bis[(N,N,N′,N′-tetramethylethylenediamine)copper (II)] chloride (Cu/TMEDA) and 5.7 mL of tetramethylethylenediamine (TMEDA) are placed in a 3 L volume of two-necked flask and thoroughly dissolved, and oxygen is supplied at a rate of 10 mL/min. Then, 13.8 g of 2-allyl-6-methylphenol and 103 g of 2,6-dimethylphenol are dissolved in 0.38 L of toluene and added dropwise to the flask, and the mixture is allowed to react at 40° C. for 6 hours while stirring at a rotation speed of 600 rpm. After the reaction is completed, a mixture of 20 L of methanol and 22 mL of concentrated hydrochloric acid is added to cause reprecipitation, and the precipitate is filtered out and dried at 80° C. for 24 hours to obtain a polyphenylene ether resin having a linear structure.

Examples of commercially available polyphenylene ether resins having a linear structure include Noryl (trademark) SA9000 and Noryl (trademark) SA90 (both manufactured by SHPP Japan LLC).

Alternatively, a polyphenylene ether resin having a branched structure synthesized by the following procedure can also be used as the polyphenylene ether resin. First, 5.3 g of di-μ-hydroxo-bis[(N,N,N′,N′-tetramethylethylenediamine)copper (II)] chloride (Cu/TMEDA) and 5.7 mL of tetramethylethylenediamine (TMEDA) are placed in a 3 L volume of two-necked flask and thoroughly dissolved, and oxygen is supplied at a rate of 10 mL/min. Then, 10.1 g of o-cresol, 91.1 g of 2,6-dimethylphenol, and 13.8 g of 2-allylphenol as raw material phenols are dissolved in 1.5 L of toluene to prepare a raw material solution. This raw material solution is added dropwise to the flask, and the mixture is allowed to react at 40° C. for 6 hours while stirring at a rotation speed of 600 rpm. After the reaction is completed, a mixture of 20 L of methanol and 22 mL of concentrated hydrochloric acid is added to cause reprecipitation, and the precipitate is filtered out and dried at 80° C. for 24 hours to obtain a polyphenylene ether resin having a branched structure.

The content of the polyphenylene ether resin in the curable resin composition of the present invention is not particularly limited as long as the effects of the present invention are achieved, but is preferably 20 to 80% by mass on a solid amount basis, relative to the total mass of the curable resin composition. If the content of the polyphenylene ether resin is 20% by mass or more, the embeddability and flexibility of the curable resin composition is ensured, and a cured product with good low dielectric properties can be formed. On the other hand, if the content of the polyphenylene ether resin is 80% by mass or less, the suitability of the curable resin composition for processes such as lamination and plating is ensured.

### (Styrene-Based Elastomer Resin)

The curable resin composition of the present invention comprises a styrene-based elastomer resin having a soft segment (soft block) composed of styrene and one or more monomers other than styrene, a melt flow rate (hereinafter also referred to as “MFR”) of 15.0 g/10 min or less, and a styrene ratio of 65% by mass or more. In the present specification, the “MFR” of the styrene-based elastomer resin refers to the MFR measured in accordance with ISO 1133 at a temperature of 230° C. and a pressure of 2.16 kg. If the curable resin composition comprises such a specific styrene-based elastomer resin, the increase in fluidity of the curable resin composition of the present invention at high temperatures can be suppressed, thereby suppressing the occurrence of gaps that cause swelling in the cured product. The styrene-based elastomer resin may be used alone or in combination of two or more types.

The soft segment of the styrene-based elastomer resin comprises styrene, and also comprises one or more monomers other than styrene within a range that satisfies the above-mentioned MFR. Examples of the monomers other than styrene that constitute the soft segment include ethylene, propylene, butylene, butadiene, isoprene and the like.

Here, examples of raw material monomers for styrene-based elastomer resins include not only styrene but also styrene derivatives such as α-methylstyrene, 3-methylstyrene, 4-propylstyrene, 4-cyclohexylstyrene and the like.

Specific examples of the styrene-based elastomer resins include those comprising a styrene monomer in the soft segment of various styrene-based elastomer resins, such as styrene-butadiene copolymers such as styrene-butadiene-styrene block copolymer, styrene-butadiene-butylene-styrene block copolymer and the like; styrene-isoprene copolymers such as styrene-isoprene-styrene block copolymer and the like; and styrene-ethylene copolymers such as styrene-ethylene-butylene-styrene block copolymer, styrene-ethylene-propylene-styrene block copolymer and the like. In order to improve the dielectric properties of the resulting cured product, it is preferable to use a styrene-based elastomer resin that does not have an unsaturated carbon bond, such as a styrene-ethylene-butylene-styrene block copolymer, that comprises a styrene monomer in the soft segment.

The styrene ratio of the soft segment is not particularly limited as long as the MFR of the styrene elastomer resin satisfies the above-mentioned range, and can be, for example, 20 to 80% by mass.

The MFR of the styrene-based elastomer resin is 15.0 g/10 min or less, preferably 10 g/10 min or less, more preferably 9 g/10 min or less, even more preferably 7 g/10 min or less, and particularly preferably 5 g/10 min or less. If the MFR of the styrene-based elastomer resin is 15.0 g/10 min or less, the flow of the curable resin composition is suppressed during processes such as reflow in which the composition is exposed to high temperatures, and thereby suppressing the occurrence of voids that could be the starting point for swelling can be suppressed. The MFR of the styrene-based elastomer resin is not particularly limited as long as the effects of the present invention are achieved, but can be, for example, 1 g/10 min or more, 2 g/10 min or more, 3 g/10 min or more, or 4 g/10 min or more.

The styrene ratio of the styrene-based elastomer resin is 65% by mass or more, and can be, for example, 66% by mass or more, or 67% by mass or more. If the styrene ratio of the styrene-based elastomer resin is 65% by mass or more, the proportion of double bonds present in the soft segments is reduced, thereby improving the dielectric properties of the cured product of the curable resin composition. On the other hand, the styrene ratio of the styrene-based elastomer resin is not particularly limited as long as the effects of the present invention are achieved, but can be, for example, 75% by mass or less, 74% by mass or less, 73% by mass or less, 72% by mass or less, 71% by mass or less, or 70% by mass or less. If the styrene ratio of the styrene-based elastomer resin is 75% by mass or less, the flexibility of the cured product of the curable resin composition can be improved. In the present specification, the “styrene ratio” of the styrene-based elastomer resin means the percentage of the mass of styrene (i.e., the total mass of styrene in the styrene portion (i.e., the hard segment) and the soft segment) relative to the total mass of the styrene-based elastomer resin.

The compatibility of the styrene elastomer resin is not particularly limited as long as the effects of the present invention are achieved, but the SP value (Hildebrand solubility parameter) of the soft segment constituting the styrene elastomer resin is preferably 19.0 or less. On the other hand, the compatibility of the styrene elastomer resin is preferably such that the SP value of the soft segment is 17.0 or more. If the SP value of the soft segment of the styrene elastomer resin is 17.0 to 19.0, the compatibility of the soft segment with PPE can be improved.

The soft segments of the styrene-based elastomer resin are preferably partially hydrogenated, and particularly preferably fully hydrogenated. If the soft segments of the styrene-based elastomer resin is hydrogenated, the dielectric properties of the cured product of the curable resin composition can be improved, and if the soft segments of the styrene-based elastomer resin is fully hydrogenated, the dielectric properties of the cured product of the curable resin composition can be particularly improved. The term “hydrogenated” means that hydrogen is added to the double bonds of the polybutadiene constituting the soft segments of the styrene-based elastomer resin. Specifically, “partially hydrogenated” means that the double bonds of the polybutadiene constituting the soft segments of the styrene-based elastomer resin is partially hydrogenated (hydrogen is added), and “fully hydrogenated” means that the double bonds of the polybutadiene constituting the soft segments of the styrene-based elastomer resin is completely hydrogenated (hydrogen is added).

In a preferred embodiment, the styrene-based elastomer resin has a soft segment SP value of 17.0 or more or is fully hydrogenated. In a particularly preferred embodiment, the styrene-based elastomer resin has a soft segment SP value of 17.0 or more and is fully hydrogenated.

Examples of commercially available styrene-based elastomers include hydrogenated styrene-based thermoplastic elastomers S.O.E. (registered trademark) S1605 (fully hydrogenated), S1609 (partially hydrogenated) (both manufactured by Asahi Kasei Corporation) and the like.

The content of the styrene-based elastomer resin in the curable resin composition of the present invention is not particularly limited as long as the effects of the present invention are achieved, but is preferably 5 to 60 parts by mass, more preferably 10 to 50 parts by mass, and even more preferably 15 to 40 parts by mass on a solid amount basis, relative to 100 parts by mass of the polyphenylene ether resin in the curable resin composition. If the content of the styrene-based elastomer resin is 5 parts by mass or more relative to 100 parts by mass of the polyphenylene ether resin, the flexibility of the cured product of the curable resin composition can be improved, and the adhesion to other components such as conductor layers can be improved. On the other hand, if the content of the styrene-based elastomer resin is 60 parts by mass or less relative to 100 parts by mass of the polyphenylene ether resin, deformation of the cured product of the curable resin composition at high temperatures can be suppressed.

### (Polymerization Initiator)

The curable resin composition of the present invention comprises a polymerization initiator. Examples of the polymerization initiator include a radical polymerization initiator, an anionic polymerization initiator, a cationic polymerization initiator and the like. The polymerization initiator may be those generating active species (radicals, cations, anions and the like) upon irradiation with light (ultraviolet rays, electron beams and the like) (a photopolymerization initiator), or those generating active species upon heating (a thermal polymerization initiator). As the polymerization initiator, a radical polymerization initiator that generates radicals upon heat or light irradiation (i.e., a photoradical polymerization initiator or a thermal radical polymerization initiator) is preferably used, and a thermal radical polymerization initiator is particularly preferably used. The polymerization initiator may be used alone or in combination of two or more types.

The thermal radical polymerization initiator is not particularly limited as long as it generates radicals by heat, i.e., is a thermal radical polymerizable initiator, and conventionally known initiators can be used. Examples of the thermal radical polymerization initiators include methyl ethyl ketone peroxide, methyl acetoacetate peroxide, acetylacetone peroxide, 1,1-bis(t-butylperoxy)cyclohexane, 2,2-bis(t-butylperoxy) butane, t-butyl hydroperoxide, cumene hydroperoxide, diisopropylbenzene hydroperoxide, 2,5-dimethylhexane-2,5-dihydroperoxide, 1,1,3,3-tetramethylbutyl hydroperoxide, di-t-butyl hydroperoxide, t-butyl hydroperoxide, dicumyl peroxide, 2,5-dimethyl-2,5-di(t-butylperoxy) hexane, 2,5-dimethyl-2,5-di(t-butylperoxy)hexyne, 2,5-dimethyl-2,5-di(t-butylperoxy)-3-butene, acetyl peroxide, octanoyl peroxide, lauroyl peroxide, benzoyl peroxide, m-toluyl peroxide, diisopropyl peroxydicarbonate, t-butylene peroxybenzoate, di-t-butyl peroxide, t-butylperoxyisopropyl monocarbonate, α,α′-bis(t-butylperoxy-m-isopropyl)benzene, α,α′-di(t-butylperoxy)diisopropylbenzene, azobisisobutyronitrile, azobisisovaleronitrile, 2,3-diphenylbutane and the like. The thermal radical polymerization initiator may be used alone or in combination of two or more types.

An example of a commercially available thermal radical polymerization initiator includes Perbutyl (registered trademark) P40 (manufactured by NOF Corporation).

From the viewpoints of ease of handling and reactivity, the thermal radical polymerization initiator preferably used has a one-minute half-life temperature of 130 to 180° C. A thermal radical polymerization initiator having a one-minute half-life temperature of 130 to 180° C. has a relatively high reaction initiation temperature, thereby suppressing curing in situations where curing is not required, such as during drying, and also has low volatility, thereby suppressing evaporation during drying and storage, thereby enabling the curable resin composition to have good storage stability.

Furthermore, a photopolymerization initiator can also be used as the polymerization initiator. The photopolymerization initiator is not particularly limited as long as it generates radicals upon irradiation with light such as UV, i.e., is a photoradical polymerizable initiator, and conventionally known initiators can be used. Examples of the photopolymerization initiators include those having an oxime ester structure, an α-aminoacetophenone structure, a hydroxyacetophenone structure, an acylphosphine oxide structure, a benzoin structure, a benzophenone structure, an acetophenone structure, a thioxanthone structure, an anthraquinone structure, a ketal structure, a benzoic acid ester structure, a titanocene structure and the like. Among these, a photopolymerization initiator having an oxime ester structure is preferably used. The photopolymerization initiator may be used alone, or in combination of two or more types.

Examples of photopolymerization initiators having an oxime ester structure include 2-(benzoyloxyimino)-1-[4-(phenylthio)phenyl]octan-1-one (OXE01), [1-[9-ethyl-6-(2-methylbenzoyl)carbazol-3-yl]ethylideneamino]acetate, ethanone-1-[9-ethyl-6-(2-methylbenzoyl)-9H-carbazol-3-yl]-1-(O-acetyloxime) (OXE02) and the like.

Furthermore, a photothermal dual polymerization initiator can also be used as the polymerization initiator. The photothermal dual polymerization initiator is not particularly limited as long as it generates radicals upon both irradiation with light such as UV and heating, i.e., is an initiator that is both photoradical polymerizable and thermal radical polymerizable, and conventionally known initiators can be used. Examples of the photothermal dual polymerization initiators are preferably peroxides having a peroxide such structure (—O—O—), as 3,3,4,4-tetra(t-butylperoxycarbonyl)benzophenone, 2-(1-t-butylperoxy-1-methylethyl)-9H-thioxanthen-9-one and the like.

The content of the polymerization initiator in the curable resin composition of the present invention is not particularly limited as long as the effects of the present invention are achieved, but is preferably 0.01 to 20% by mass, more preferably 0.05 to 10% by mass, and even more preferably 0.1 to 10% by mass on a solid amount basis, relative to the total mass of the curable resin composition. If the content of the polymerization initiator is within the above-mentioned range, deterioration of the film quality when the curable resin composition is formed into a coating film can be prevented.

### (Filler)

The curable resin composition of the present invention may comprise a filler as needed to increase the physical strength of the coating film. Known inorganic or organic fillers can be used as such fillers, with barium sulfate, spherical silica, hydrotalcite and talc being particularly preferred. Furthermore, metal oxides and metal hydroxides such as titanium oxide, aluminum hydroxide and the like can be used as extender pigment fillers to achieve a white appearance and flame retardancy.

An example of a commercially available filler includes silica-comprising slurry SC2050-HNF (manufactured by Admatechs Co., Ltd.).

The content of the filler in the curable resin composition of the present invention is not particularly limited as long as the effects of the present invention are achieved, but is preferably 80% by mass or less relative to the total mass of the curable resin composition. If the filler content is more than 80% by mass, the viscosity of the curable resin composition becomes excessively high, resulting in reduced coatability and moldability, and the cured product of the curable resin composition becoming brittle. Particularly preferably, the content of the filler in the curable resin composition is 10 to 80% by mass relative to the total mass of the curable resin composition. If the filler content is 10 to 80% by mass relative to the total mass of the curable resin composition, deformation of the cured product due to temperature changes can be prevented while adhesion between the cured product of the curable resin composition and other components such as a conductor layer is ensured.

### (Radical Reactive Monomer)

The curable resin composition of the present invention may comprise a radical reactive monomer. In the present specification, “radical reactive” includes a monomer having a radical polymerizable group. Any conventionally known radical reactive monomer can be used. Furthermore, the radical polymerizable group is preferably a group having an unsaturated carbon bond, and examples thereof include a vinyl group, an allyl group, a maleimide group, an acrylic group, a methacrylic group, a styryl group and the like. If the curable resin composition of the present invention comprises a radical reactive monomer, the concentration of the radical polymerizable group in the curable resin composition increases, thereby improving the crosslink density.

Examples of the radical reactive monomers include (meth)acrylic acid and esters thereof such as (meth)acrylic acid, methyl (meth)acrylate, ethyl (meth)acrylate, butyl (meth)acrylate, 2-ethylhexyl (meth)acrylate and the like; (meth)acrylamide derivatives such as (meth)acrylamide, isopropylacrylamide and the like; vinyl monomers such as vinyl chloride, vinylidene chloride, vinyl acetate, methyl vinyl ether, styrene, divinylbenzene, (meth)acrylonitrile and the like; compounds having an unsaturated double bond such as isoprene and the like; polyfunctional monomers such as pentaerythritol tri(meth)acrylate and the like; and (meth)acryloylmorpholine. The radical reactive monomer may be used alone or in combination of two or more types.

A monomer having two or more vinyl groups in the molecule is preferably used as the radical reactive monomer. Examples of monomers having two or more vinyl groups in the molecule include triallyl isocyanurate, triallyl cyanurate, diallyl phthalate, diallyl isophthalate and the like. If the radical reactive monomer has two or more vinyl groups, three-dimensional crosslinking is formed in the cured product of the curable resin composition of the present invention, thereby improving its mechanical properties. Furthermore, a monomer having a triazine ring in the molecule is preferably used as the radical reactive monomer. That is, a monomer having a triazine ring and two or more vinyl groups in the molecule is particularly preferably used as the radical reactive monomer. If the curable resin composition of the present invention comprises a highly reactive radical reactive monomer, particularly a monomer having two or more vinyl groups and a triazine ring in the molecule, the dielectric properties of the cured product of the curable resin composition of the present invention can be improved.

An example of a commercially available radical reactive monomer includes TAIC (trademark) (triallyl isocyanurate, manufactured by Mitsubishi Chemical Corporation).

The content of the radical reactive monomer in the curable resin composition of the present invention is not particularly limited as long as the effects of the present invention are achieved, but is preferably 10 to 40% by mass on a solid amount basis relative to the total mass of the curable resin composition. If the content of the radical reactive monomer is 10% by mass or more, the crosslink density in the curable resin composition described above can be sufficiently improved. On the other hand, if the content of the radical reactive monomer is 40% by mass or less, the curable resin composition can be cured without impairing the effect of reducing the dielectric constant.

### (Thermosetting Component)

The curable resin composition of the present invention may comprise a thermosetting component. Examples of the thermosetting component include known and commonly used components such as isocyanate compounds, blocked isocyanate compounds, amino resins, maleimide compounds, benzoxazine resins, carbodiimide resins, cyclocarbonate compounds, epoxy compounds, oxetane compounds, episulfide resins and the like. The thermosetting component may be used alone or in combination of two or more types.

The thermosetting component is preferably an epoxy resin. Examples of the epoxy resins include bisphenol A type epoxy resin, bisphenol F type epoxy resin, hydrogenated bisphenol A type epoxy resin, brominated bisphenol A type epoxy resin, bisphenol S type epoxy resin, phenol novolac type epoxy resin, cresol novolac type epoxy resin, bisphenol A type novolac epoxy resin, biphenyl type epoxy resin, naphthalene type epoxy resin, dicyclopentadiene type epoxy resin, triphenylmethane type epoxy resin and the like.

### (Organic Solvent)

The curable resin composition may comprise an organic solvent for the purpose of adjusting the viscosity during preparation thereof or when applying the curable resin composition onto a substrate or film to form a resin layer. Examples of the organic solvents include known and commonly used organic solvents such including ketones such as methyl ethyl ketone, cyclohexanone and the like; aromatic hydrocarbons such as toluene, xylene, tetramethylbenzene and the like; glycol ethers such as anisole, cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, diethylene glycol monomethyl ether acetate, tripropylene glycol monomethyl ether and the like; esters such as ethyl acetate, butyl acetate, butyl lactate, cellosolve acetate, butyl cellosolve acetate, carbitol acetate, butyl carbitol acetate, propylene glycol monomethyl ether acetate, dipropylene glycol monomethyl ether acetate, propylene carbonate and the like; aliphatic hydrocarbons such as octane, decane and the like; and petroleum-based solvents such as petroleum ether, petroleum naphtha, solvent naphtha and the like. The organic solvents may be used alone or in combination of two or more types.

The organic solvent can be evaporated and dried using a hot air circulation drying furnace, an IR furnace, a hot plate, a convection oven or the like (a method of bringing hot air in a dryer into countercurrent contact using one provided with an air heating type heat source using steam and a method of blowing the hot air on a support using a nozzle).

### (Other Ingredients)

The curable resin composition may further comprise, as necessary, components such as dispersants, photoinitiator assistants, cyanate compounds, mercapto compounds, urethanization catalysts, thixotropic agents, adhesion promoters, block copolymers, chain transfer agents, polymerization inhibitors, copper inhibitors, antioxidants, rust inhibitors, thickeners such as organic bentonite, montmorillonite and the like, at least one of silicone-based, fluorine-based and polymer-based antifoaming agents and leveling agents, imidazole-based, thiazole-based and triazole-based silane coupling agents, and flame retardants such as phosphinates, phosphate ester derivatives and phosphorus compounds including phosphazene compounds. These may be those known in the field of electronic materials.

The curable resin composition of the present invention preferably comprises substantially no dispersant. Specifically, the content of the dispersant in the curable resin composition of the present invention can be, for example, 0.5% by mass or less relative to the total mass of the curable resin composition. Since the incorporation of a dispersant can cause the cured product of the curable resin composition to swell at high temperatures, swelling of the cured product at such high temperatures can be suppressed by making the curable resin composition substantially free of a dispersant.

The curable resin composition of the present invention may be used in a liquid form or may be used in the form of a dry film as described below. When the curable resin composition is used in a liquid form, the composition may be one-component or two or more-component.

### [Dry Film]

According to another aspect of the present invention, there is provided a dry film having a first film and a resin layer provided on the first film and consisting of the curable resin composition of the present invention (hereinafter also referred to as the “dry film of the present invention”). The first film in the dry film of the present invention refers to a film that is adhered to the resin layer of the dry film at least when the dry film is laminated onto a base material such as a substrate by heating or the like and forms an integral structure so that the resin layer provided on the dry film and consisting of the curable resin composition is in contact with the base material. The first film may be peeled from the resin layer in a step after lamination. To form the dry film, the curable resin composition of the present invention is diluted with an organic solvent such as those described above to adjust the viscosity to an appropriate level, and then coated onto the first film to a uniform thickness using a comma coater, a blade coater, a lip coater, a rod coater, a squeeze coater, a reverse coater, a transfer roll coater, a gravure coater, a spray coater or the like, and then typically dried at a temperature of 50 to 130° C. for 1 to 30 minutes to obtain a film. The thickness of the coating film is not particularly limited, but is generally selected appropriately within the range of 1 to 150 μm, preferably 5 to 60 μm as the thickness after drying.

The first film is not particularly limited, and any known film can be used, and examples of suitable films include polyester films such as polyethylene terephthalate, polyethylene naphthalate and the like; and films made of thermoplastic resins such as polyimide films, polyamideimide films, polypropylene films, polystyrene films, and the like. Among these, polyester films are preferred from the viewpoints of heat resistance, mechanical strength, ease of handling and the like. A laminate of these films can also be used as the first film.

Moreover, from the viewpoint of improving mechanical strength, the thermoplastic resin film as described above is preferably a film that has been oriented in a uniaxial or biaxial direction.

The thickness of the first film is not particularly limited, but can be, for example, 10 μm to 150 μm.

After forming a resin layer of the curable resin composition of the present invention on the first film, it is preferable to further laminate a peelable second film on the surface of the resin layer for the purpose of preventing dust from adhering to the surface of the resin layer. The second film refers to a film that is peeled from the resin layer of the dry film before lamination when the dry film is laminated onto a base material such as a substrate by heating or the like and forms an integral structure so that the resin layer provided on the dry film is in contact with the base material. A polyethylene film, a polytetrafluoroethylene film, a polypropylene film, a surface-treated paper and the like can be used as the peelable second film, and any film can be used as long as the adhesive strength between the resin layer and the second film is smaller than the adhesive strength between the resin layer and the first film when the second film is peeled off.

The thickness of the second film is not particularly limited, but can be, for example, 10 μm to 150 μm.

In the dry film of the present invention, the curable resin composition of the present invention may be applied to the second film described above and dried to form a resin layer, and the first film may be laminated on the surface of the resin layer. That is, when producing the dry film of the present invention, either the first film or the second film may be used as the film to which the curable resin composition of the present invention is applied.

### [Cured Product]

According to another aspect of the present invention, there is provided a cured product obtained by curing the curable resin composition of the present invention or the resin layer of the dry film of the present invention (hereinafter also referred to as “cured product of the present invention”). The cured product of the present invention has excellent dielectric properties and is therefore suitable for use as an interlayer insulating material in electronic devices that transmit high-frequency signals.

The conditions for curing the curable resin composition or the resin layer of the dry film of the present invention are not particularly limited as long as they are general conditions used for curing resin compositions, and can be set appropriately depending on, for example, the type of polymerization initiator comprised in the curable resin composition. For example, when a thermal radical polymerization initiator is used as the polymerization initiator, the layer of the curable resin composition formed on the substrate can be cured by heating at a temperature of 100 to 300° C. for 1 to 120 minutes.

### [Printed Wiring Board]

According to another aspect of the present invention, there is provided a printed wiring board having the cured product of the present invention described above (hereinafter also referred to as the “printed wiring board of the present invention”). That is, the printed wiring board of the present invention has a cured product obtained from the curable resin composition of the present invention or the resin layer of the dry film of the present invention. A method for producing the printed wiring board of the present invention includes, for example, adjusting the viscosity of the curable resin composition of the present invention to a level suitable for the coating method using an organic solvent as described above, applying it to a base material by a method such as dip coating, flow coating, roll coating, bar coating, screen printing, curtain coating or the like, and then evaporating and drying (pre-drying) the organic solvent comprised in the composition at a temperature of 60 to 100° C. to form a tack-free resin layer. In addition, in the case of a dry film, the resin layer is formed on the base material by laminating it onto the base material using a laminator or the like so that the resin layer contacts the base material.

Examples of the base material constituting the printed wiring board of the present invention include printed wiring boards and flexible printed wiring boards on which circuits have been formed in advance using copper and the like, and copper-clad laminates of all grades (FR-4 and the like) which use materials such as copper-clad laminates for high-frequency circuits made of materials such as paper phenol, paper epoxy, glass cloth epoxy, glass polyimide, glass cloth/non-woven cloth epoxy, glass cloth/paper epoxy, synthetic fiber epoxy, fluororesin/polyethylene/polyphenylene ether, polyphenylene oxide/cyanate and the like, as well as metal substrates, polyimide films, polyethylene terephthalate films, polyethylene naphthalate (PEN) films, glass substrates, ceramic substrates, wafer plates and the like.

The dry film resin layer is preferably bonded to the base material under pressure and heat using a vacuum laminator or the like. By using such a vacuum laminator, when a circuit-formed substrate is used, the dry film adheres tightly to the circuit board even if the circuit board surface is uneven, preventing the inclusion of air bubbles and improving the ability to fill recesses in the substrate surface. The pressure condition is preferably about 0.1 to 2.0 MPa, and the heating condition is preferably 40 to 140° C.

The evaporating and drying performed after applying the layer of the curable resin composition of the present invention on the base material can be performed using a hot air circulation drying furnace, an IR furnace, a hot plate, a convection furnace or the like (a method of bringing hot air in a dryer into countercurrent contact using one provided with an air heating type heat source using steam and a method of blowing the hot air on a support using a nozzle).

The layer of the curable resin composition formed on the substrate is then heat-cured to obtain a printed wiring board having a cured product of the curable resin composition. The heat-curing of the layer of the curable resin composition can be performed, for example, by heating at 150 to 250° C. for 30 to 90 minutes.

### EXAMPLE

Hereinafter, the present invention will be described in more detail with reference to Examples, but the present invention is not limited to these Examples. In the Examples, the numerical values for each component mean parts by mass unless otherwise specified.

### (Synthesis of Polyphenylene Ether Resin Having a Linear Structure)

A polyphenylene ether resin having a linear structure was synthesized according to the following procedure. First, 5.3 g of di-μ-hydroxo-bis[(N,N,N′,N′-tetramethylethylenediamine)copper (II)] chloride (Cu/TMEDA) and 5.7 mL of tetramethylethylenediamine (TMEDA) were placed in a 3 L volume of two-necked flask and thoroughly dissolved, and oxygen was supplied at a rate of 10 mL/min. Then, 13.8 g of 2-allyl-6-methylphenol and 103 g of 2,6-dimethylphenol were dissolved in 0.38 L of toluene and added dropwise to the flask, and then the mixture was stirred at 600 rpm at 40° C. for 6 hours to react. After the reaction was completed, a mixture of 20 L of methanol and 22 mL of concentrated hydrochloric acid was added to the mixture to cause reprecipitation, and then the precipitate was filtered and dried at 80° C. for 24 hours to obtain a polyphenylene ether resin having a linear structure.

### (Synthesis of Polyphenylene Ether Resin Having a Branched Structure)

A polyphenylene ether resin having a branched structure was synthesized according to the following procedure. First, 5.3 g of di-μ-hydroxo-bis[(N,N,N′,N′-tetramethylethylenediamine)copper (II)] chloride (Cu/TMEDA) and 5.7 mL of tetramethylethylenediamine (TMEDA) were placed in a 3 L volume of two-necked flask and thoroughly dissolved, and oxygen was supplied at a rate of 10 mL/min. Then, 10.1 g of o-cresol, 91.1 g of 2,6-dimethylphenol, and 13.8 g of 2-allylphenol as raw material phenols were dissolved in 1.5 L of toluene to prepare a raw material solution. This raw material solution was added dropwise to the flask, and the mixture was allowed to react at 40° C. for 6 hours while stirring at 600 rpm. After the reaction was completed, a mixture of 20 L of methanol and 22 ml of concentrated hydrochloric acid was added to cause reprecipitation, and the precipitate was filtered and dried at 80° C. for 24 hours to obtain a polyphenylene ether resin having a branched structure.

### [Preparation of Curable Resin Composition]

Respective components shown in the following Table 1 were mixed in the amounts shown in the table (solid content is shown for all components except the organic solvent) to prepare curable resin compositions for Examples 1 to 3 and Comparative Examples 1 to 3. Specifically, polyphenylene ether resin and styrene-based elastomer resin were mixed with an organic solvent (toluene or anisole), and the mixture was thoroughly stirred in a planetary centrifugal mixer to achieve complete dissolution, obtaining a polyphenylene ether resin solution. Triallyl isocyanurate and spherical silica filler were added to the resulting polyphenylene ether resin solution, and the mixture was stirred in a planetary centrifugal mixer. Then, α,α′-di(t-butylperoxy)diisopropylbenzene was added, and the mixture was further stirred in a planetary centrifugal mixer to obtain each curable resin composition. Details of each component in Table 1 are as follows:

Linear polyphenylene ether resin: A polyphenylene ether resin having a linear structure synthesized according to the procedure described above.

Branched polyphenylene ether resin: A polyphenylene ether resin having a branched structure synthesized according to the procedure described above.

Styrene-based elastomer resin A: S.O.E. (registered trademark) S1605 (manufactured by Asahi Kasei Corporation, melt flow rate 4.7 g/10 min, styrene ratio 67%, fully hydrogenated)

Styrene-based elastomer resin B: S.O.E. (registered trademark) S1609 (manufactured by Asahi Kasei Corporation, melt flow rate 9.4 g/10 min, styrene ratio 67%, partially hydrogenated)

Styrene-based elastomer resin C: S.O.E. (registered trademark) S1611 (manufactured by Asahi Kasei Corporation, melt flow rate 12.3 g/10 min, styrene ratio 63%, partially hydrogenated)

Styrene-based elastomer resin D: Tuftec (registered trademark) P5051 (manufactured by Asahi Kasei Corporation, melt flow rate 16.9 g/10 min, styrene ratio 47%, partially hydrogenated)

Styrene-based elastomer resin E: Tuftec (registered trademark) P2000 (manufactured by Asahi Kasei Corporation, melt flow rate 24.7 g/10 min, styrene ratio 67%, partially hydrogenated)

Polymerization initiator: Perbutyl (registered trademark) P40 (thermal radical polymerization initiator, manufactured by NOF Corporation)

Inorganic filler: Silica-comprising slurry SC2050-HNF (manufactured by Admatechs Co., Ltd.)

Radical reactive monomer: Triallyl isocyanurate (TAIC (trademark), manufactured by Mitsubishi Chemical Corporation)

Organic solvent A: Toluene (manufactured by Fujifilm Wako Pure Chemical Industries, Ltd.)

Organic solvent B: Anisole (manufactured by Tsujimoto Chemical Industry Co., Ltd.)

Styrenic elastomer resins A to C all have hard segments (styrene segments) and soft segments, and the soft segments comprise styrene and one or more monomers other than styrene. Although the SP values (Hildebrand solubility parameters) of styrene elastomer resins A to E have not been made public, it has been confirmed that the SP values of styrene elastomer resins A and B are 17.0 or higher.

TABLE 1

| | | Example | Example | Example | Comparative | Comparative | Comparative |
|---|---|---|---|---|---|---|---|
| Ingredient name | | 1 | 2 | 3 | Example 1 | Example 2 | Example 3 |
| Linear polyphenylene | | 100 | 0 | 0 | 0 | 0 | 0 |
| ether resin | | | | | | | |
| Branched | | 0 | 100 | 100 | 100 | 100 | 100 |
| polyphenylene ether | | | | | | | |
| resin | | | | | | | |
| Styrene-based | | 30 | 30 | 0 | 0 | 0 | 0 |
| elastomer resin A | | | | | | | |
| Styrene-based | | 0 | 0 | 30 | 0 | 0 | 0 |
| elastomer resin B | | | | | | | |
| Styrene-based | | 0 | 0 | 0 | 30 | 0 | 0 |
| elastomer resin C | | | | | | | |
| Styrene-based | | 0 | 0 | 0 | 0 | 30 | 0 |
| elastomer resin D | | | | | | | |
| Styrene-based | | 0 | 0 | 0 | 0 | 0 | 30 |
| elastomer resin E | | | | | | | |
| Polymerization initiator | | 5 | 5 | 5 | 5 | 5 | 5 |
| Inorganic filler | | 100 | 100 | 100 | 100 | 100 | 100 |
| Radical reactive | | 50 | 50 | 50 | 50 | 50 | 50 |
| monomers | | | | | | | |
| Organic solvent A | | 250 | 0 | 0 | 0 | 0 | 0 |
| Organic solvent B | | 0 | 250 | 250 | 250 | 250 | 250 |
| Evaluation | Reflow | ◯ | ◯ | ◯ | ◯ | X | X |
| items | resistance | | | | | | |
| | Storage | ◯ | ◯ | ◯ | ◯ | X | X |
| | stability | | | | | | |
| | Dielectric | ◯ | ◯ | Δ | X | X | X |
| | properties | | | | | | |

### [Evaluation of Storage Stability]

The storage stability of each curable resin composition of the Examples and Comparative Examples was evaluated according to the following procedure. First, each curable resin composition was placed in a white plastic container (Hi-Resist BHR-150, manufactured by Kinki Yoki Co., Ltd.) and allowed to stand for 7 days in a place not exposed to light. Then, the state of the curable resin composition before and after standing was visually confirmed, and the storage stability was evaluated according to the following criteria. The evaluation results are shown in Table 1.
◯: The curable resin composition did not turn into a gel or undergo phase separation, was in a state where it could be well coated, and had excellent storage stability.
x: The curable resin composition turned into a gel and undergo phase separation, was in a state where it could not be coated, and had insufficient storage stability.

### [Preparation of Dry Film for Evaluation]

Each of the curable resin compositions of Examples and Comparative Examples obtained according to the procedure described above was applied to a first film (highly smooth grade PET film R80, manufactured by Toray Industries, Inc.) having a thickness of 38 μm using an applicator so that the film thickness after drying would be 35 μm, and the film was dried by heating at 90° C. for 15 minutes in a hot air circulation drying furnace to form a resin layer to obtain each dry film for evaluation.

### [Preparation of Substrate for Evaluation]

Both surfaces of a substrate (copper clad laminate CCL-HL832NX, TYPE A Series, manufactured by Mitsubishi Gas Chemical Company, Inc., thickness 0.4 mm) are roughened under conditions such that the etching depth was approximately 1 μm using a roughening agent (CZ8100, manufactured by MEC Co., Ltd.) to prepare a CZ-treated substrate.

Then, each dry film for evaluation was placed on both sides of the CZ-treated substrate so that the resin layer of each dry film was in contact with the surface of the substrate. Then the dry films were laminated at 140° C. and 0.8 MPa using a vacuum laminator (CVP-600, manufactured by Nikko Materials Co., Ltd.), and cured by heat treatment for 60 minutes in an air atmosphere at 200° C. in a hot air circulation dry furnace to prepare a substrate having a cured product of each resin layer.

Then, the surface of each substrate was subjected to a desmear treatment using a commercially available desmear treatment solution. Specifically, the substrates obtained by pealing the first film from the resin layer were immersed in a swelling solution (Swelling Dip Securigant P, manufactured by Atotech Japan Co., Ltd.) at 60° C. for 5 minutes. Then, the substrates were immersed in a roughening solution (Concentrate Compact CP, manufactured by Atotech Japan Co., Ltd.) at 80° C. for 20 minutes, and further immersed in a neutralizing solution (Reduction Securigant P500, manufactured by Atotech Japan Co., Ltd.) at 40° C. for 5 minutes.

Then, the surface of each substrate was subjected to electroless plating and electrolytic plating to form a copper plating layer. Specifically, the electroless plating was performed by immersing the substrate in a cleaner treatment solution (Cleaner MCD-PL, manufactured by Uemura Kogyo Co., Ltd.) at 40° C. for 5 minutes and in a soft etching treatment solution (Alucup MDP-2m, manufactured by Uemura Kogyo Co., Ltd.) at 25° C. for 2 minutes. The substrate was then immersed in a catalyst imparting treatment solution (Alucup MAT-SP, manufactured by Uemura Kogyo Co., Ltd.) at 40° C. for 5 minutes, and further immersed in a reduction treatment solution (Alucup MRD-2-C/MAB-4-C/MAB-4-A, manufactured by Uemura Kogyo Co., Ltd.) at 35° C. for 3 minutes. Then the substrate was immersed in a reaction treatment accelerating treatment solution (Alucup MEL-3-A, manufactured by Uemura Kogyo Co., Ltd.) at 25° C. for 1 minute, and further immersed in an electroless plating treatment solution (Thrucup PEA V2, manufactured by Uemura Kogyo Co., Ltd.) at 36° C. for 20 minutes to perform electroless copper plating. Then the substrates were immersed in an acid cleaning solution (Acid Cleaner FR, manufactured by Atotech Japan Co., Ltd.) at 45° C. for 5 minutes, immersed in a 10% aqueous sulfuric acid solution at 25° C. for 1 minute, and further immersed in an electrolytic copper plating solution at 23° C. for 60 minutes to perform electrolytic copper plating at a current density of 2 A/dm². Then, the substrates were annealed by heating at 190° C. for 60 minutes in a hot air circulating dry furnace to obtain each substrate for evaluation

### [Evaluation of Reflow Resistance]

The reflow resistance (adhesion between the cured product and the conductor layer at high temperatures) of the cured product of each curable resin composition was evaluated according to the following procedure. First, each evaluation substrate was treated in a reflow furnace (NIS-20-82C, manufactured by Atec Techtron Co., Ltd.) under conditions of a reflow temperature of 265° C.×3 times/air. Then, each evaluation substrate after the reflow treatment was checked, and the reflow resistance was evaluated according to the following criteria. The evaluation results are shown in Table 1.
◯: The cured product of the resin layer had the proportion of the swelling area of less than 3%, and had excellent reflow resistance.
x: The cured product of the resin layer had the proportion of the swelling area of 3% or more, and had insufficient reflow resistance.

### [Preparation of Cured Product for Evaluation]

Each curable resin composition was applied to the shine side (S side) of 18 μm thick copper foil using an applicator so that the thickness of the cured product was 3 μm. The composition was then dried at 90° C. for 15 minutes in a hot air circulating drying furnace. Then the composition was cured at 200° C. for 60 minutes in an inert oven filled with nitrogen. The copper foil was then removed to obtain each cured product for evaluation.

### [Evaluation of Dielectric Properties]

The dielectric properties (dielectric constant Dk and dielectric loss tangent Df) of the cured product of each curable resin composition were evaluated according to the following procedure. First, each cured product for evaluation was cut into a length of 80 mm, a width of 45 mm, and a thickness of 30 μm to obtain a test specimen. The dielectric constant Dk and dielectric loss tangent Df of each test specimen were measured at a frequency of 10 GHz and a temperature of 25° C. using a split spot dielectric resonator (SPDR), a vector network analyzer (E5071C, manufactured by Keysight Technologies, Inc.) and a calculation program (manufactured by QWED). The dielectric properties were evaluated based on the measured values according to the following criteria. The evaluation results are shown in Table 1.
◯: The cured product had Dk of 3.0 or less and Df of 0.0015 or less, and had extremely excellent dielectric properties.
Δ: The cured product had Dk of 3.0 or less and Df of more than 0.0015 and 0.002 or less, and had excellent dielectric properties.
x: The cured product had Dk of more than 3.0 and/or Df is more than 0.002, and had insufficient dielectric properties.

From the evaluation results shown in Table 1, it can be seen that the curable resin compositions of Examples 1 to 3 have excellent storage stability, and furthermore, their cured products have excellent reflow resistance (excellent adhesion to the conductor layer at high temperatures) and dielectric properties. On the other hand, it can be seen that the curable resin composition of Comparative Example 1 has excellent storage stability, and furthermore, its cured products have excellent reflow resistance, but the dielectric properties of the cured products are insufficient. It can also be seen that the curable resin compositions of Comparative Examples 2 and 3 have insufficient storage stability, and furthermore, their cured products have insufficient reflow resistance and dielectric properties.

1. A curable resin composition comprising a polyphenylene ether resin, a styrene-based elastomer resin, and a polymerization initiator, wherein
the styrene-based elastomer resin has a soft segment, and the soft segment is composed of styrene and one or more monomers other than styrene,
the melt flow rate of the styrene-based elastomer resin is 15.0 g/10 min or less, and
the styrene ratio of the styrene-based elastomer resin is 65% by mass or more.

2. The curable resin composition according to claim 1, wherein the solubility parameter of the soft segment is 17.0 or more.

3. The curable resin composition according to claim 1, wherein the soft segment of the styrene-based elastomer resin is fully hydrogenated.

4. The curable resin composition according to claim 1, which is substantially free of a dispersant.

5. A dry film having a first film and a resin layer provided on at least one surface of the first film, wherein the resin layer consists of the curable resin composition according to claim 1.

6. A cured product of the curable resin composition according to claim 1.

7. A printed wiring board having the cured product according to claim 6.

8. A cured product of the resin layer of the dry film according to claim 5.

9. A printed wiring board having the cured product according to claim 8.
